(19) United States
(12) Patent Application Publication
(10) Pub. No.: US 2025/0086348 A1
(43) Pub. Date: Mar. 13, 2025

(54) OPERATIONAL SIMULATIONS OF DELAY COST METRICS

(71) Applicant: The Boeing Company, Arlington, VA (US)

(72) Inventor: Bronwyn A. Jackson, Seattle, WA (US)

(21) Appl. No.: 18/464,100

(22) Filed: Sep. 8, 2023

(51) Int. Cl. G06F 30/20

(52) U.S. Cl. CPC G06F 30/20

(57) ABSTRACT

Systems and methods for determining delay cost metrics in a probabilistic operational simulation for vehicles are provided. One aspect provides a computing system comprising one or more processing devices configured to execute a probabilistic operational simulation that simulates an operational environment comprising a plurality of vehicles. Multiple operational models are integrated into the probabilistic operational simulation for interaction and comprise a route model, a preparation model, a delay model, and a delay cost model. Vehicle operational data is used to run a scenario in the probabilistic operational simulation comprising operating the vehicles over a timeframe. The delay model computes delay times occurring over the timeframe, with the delay times provided to the delay cost model to compute and output delay cost metrics over the timeframe.

### FIELD

This invention is directed to the field of operational simulations and, more specifically, computing delay cost metrics using models integrated into operational simulations.

### BACKGROUND

Operational simulations can simulate operational environments in which a plurality of vehicles traverse a variety of routes. In an ideal scenario, routes are completed with vehicle arrival/departure times occurring as scheduled. However, in real world scenarios, various factors such as maintenance activities, traffic control issues, weather conditions, and a wide variety of other factors can cause delays. Such delays can result in unplanned costs being incurred by vehicle operators.

Various methods for simulating and estimating delay times and costs have been contemplated. However, in the context of complex operational environments, such as managing a fleet of aircraft that travel a variety of routes, a large number of variables and operational factors can contribute to delays and can interact to produce a wide variety of delays. Further, in some operational environments the ratio of delay time to delay costs is not a linear function.

Prior methods for simulating and estimating delay times and costs are capable of generating only high-level, conclusory information, such as monthly or yearly averages based on simplified assumptions of delay-to-cost relationships. These methods provide little assistance in analyzing actual costs and associated operational impact of delays arising from a wide variety of sources/causes across a fleet of vehicles over an extended period. For example, typical methods for delays are generally performed using separate, isolated models. In such methods, information is not shared or utilized among the models, which prevents analysts from uncovering various interactions and cascading effects that commonly occur in fleet operations. Another disadvantage of previous fault assessment models is that they are generally not time-based. They may predict general information such as the average estimated costs of delays for a year of fleet operations. Such predictions are performed on the assumption that the occurrence of delays is uniformly distributed across time. However, in real scenarios, it is not uncommon to have clusters of delays.

### SUMMARY

Systems and methods for computing delay cost metrics in a probabilistic operational simulation for a plurality of vehicles are provided. One aspect provides a computing system comprising one or more processing devices configured to execute a probabilistic operational simulation that generates interactions among a plurality of component simulations. A plurality of operational models is integrated into the probabilistic operational simulation and generates the component simulations, with the plurality of operational models comprising a route model comprising information describing a route schedule comprising a plurality of routes for the plurality of vehicles, a preparation model comprising information describing tasks to prepare a vehicle for departure, and one or more delay models for computing delay information. A delay cost model for computing delay cost metrics is also integrated into the operational simulation.

The one or more processing devices is further configured to receive operational data related to operation of the plurality of vehicles across at least a portion of the plurality of routes, and using the operational data, run a scenario in the probabilistic operational simulation comprising operating the plurality of vehicles over a timeframe. The delay model is utilized to compute a plurality of delay times occurring over the timeframe. The plurality of delay times are provided to the delay cost model to compute and output a plurality of delay cost metrics.

### BRIEF DESCRIPTION OF THE DRAWINGS

FIG. 1 shows an example computing system for performing a probabilistic operational simulation for a plurality of vehicles.

FIG. 2 shows output representing delay cost metrics output by a delay cost model in the form of stacked bar charts.

FIG. 3 shows output representing delay cost distributions over a timeframe output by a delay cost model.

FIG. 4 shows another example computing system for performing an operational simulation for a plurality of vehicles.

FIG. 5 shows output representing delay cost metrics output by a delay cost model of FIG. 4 in the form of segmented stacked bar charts.

FIG. 6 shows another example computing system for performing a probabilistic operational simulation for a plurality of vehicles.

FIG. 7 shows output representing delay cost metrics output by a delay cost model of FIG. 6 in the form of stacked bar charts.

FIGS. 8A-8D show a block diagram of an example method for determining delay cost metrics in a probabilistic operational simulation according to examples of the present disclosure.

FIG. 9 shows an example computing system in which the computing system of FIG. 1 may be instantiated.

### DETAILED DESCRIPTION

Operating a fleet of vehicles is a complex logistics operation involving a large number of systems and related components. Changes to one or more aspects of vehicle fleet operations can have wide-ranging impacts. For example, in the context of managing a fleet of aircraft, changes to flight schedules, FAA regulations, maintenance programs, airport operations, climate or natural environments, etc., can have a variety of consequences, including delays and corresponding cost implications.

Operators of vehicle fleets considering changes to their operations either do not assess the impacts of these changes or use a qualitative method based on guidance from subject matter experts, which can be flawed or misguided. Further, in many commercial and military operations, understanding actual effects and associated costs of changes to vehicle fleet operations can require collection and analysis of vast quantities of data gathered over weeks, months, or years of operations. Adding to the complexity, an operational change within one operational system can result in cascading effects in one or more other systems, thereby compounding delays and associated costs. Additionally, where costs have a non-linear relationship to delay times, predicting future costs incurred by operational changes can prove challenging.

In view of the issues described above, systems and methods for computing delay costs in a probabilistic operational simulation that generates interactions among a plurality of component simulations for a plurality of vehicles are provided. Time-based operational simulations for computing delay cost metrics can be performed using a probabilistic operational simulation that includes multiple integrated operational models that perform probabilistic or deterministic data modeling. In some implementations, the plurality of operational models includes a route model, a preparation model, and one or more delay models that characterize delays having different causes and sources. Use of greater numbers of operational models can provide operational impact assessments with higher fidelity. A delay cost model for computing delay cost metrics is also integrated into the operational simulation.

Where the vehicles are aircraft, examples of delay models that characterize delays associated with various causes and can be integrated into an event based probabilistic operational simulation include planned and unplanned maintenance, taxi and runway, air traffic control activity, and flight rule delay models. In different examples, operational simulations of the present disclosure can utilize Monte Carlo simulations and/or other suitable probabilistic modeling techniques. In this manner, by integrating one or more delay models, a delay cost model, and other operational models into a probabilistic operational simulation that simulates an operational environment of a plurality of vehicles, interactions among the component simulations generated by the models can be analyzed to determine delay times and associated delay cost metrics. Advantageously, the cost implications of different changes and combinations of changes to vehicle fleet operations can be simulated and examined to provide valuable insights into how to optimize fleet operations and reduce operational costs. Additionally, such simulations can be performed to enable long term analysis—e.g., over timeframes of months to years.

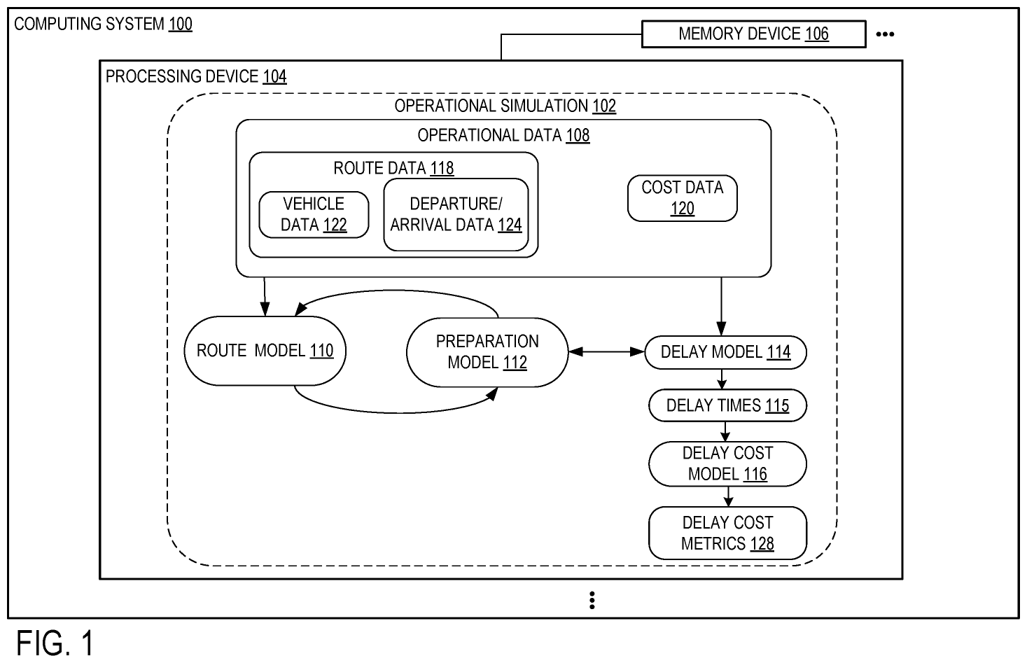

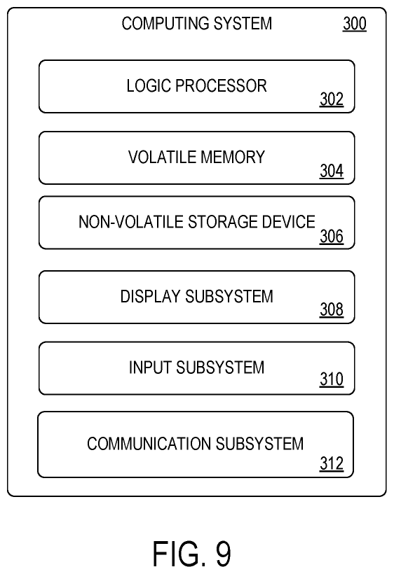

Turning now to the drawings, systems and methods for determining delay cost metrics in a probabilistic operational simulation that generates interactions among a plurality of component simulations for a plurality of vehicles are described. FIG. 1 shows an example computing system 100 for performing a probabilistic operational simulation 102 that simulates an operational environment comprising a plurality of vehicles. As shown, computing system 100 includes a processing device 104 (e.g., a logic processor such as a central processing unit (CPU)) and a memory device 106 (e.g., volatile and non-volatile memory) operatively coupled to each other. Other components such as input/output subsystems (not shown) can also be included. The memory device 106 stores instructions that, upon execution by the processing device 104, cause the processing device 104 to perform the probabilistic operational simulation 102. Additional details regarding processing device 104, memory device 106, and other components, subsystems, and algorithms of computing system 100 are described further below with reference to FIG. 9.

The probabilistic operational simulation 102 can be executed to run scenarios comprising operating the plurality of vehicles across routes from a route schedule over a timeframe. Advantageously, a delay cost model integrated into the simulation is utilized to compute delay cost metrics corresponding to delays over the timeframe for various applications. For example, operational simulation 102 can be performed to simulate passenger transit routes for fleets of aircraft, buses, or any other vehicles. The operational simulation 102 can be performed using a plurality of operational models and operational data 108. In the depicted example, the plurality of operational models includes a route model 110, a preparation model 112, a delay model 114, and a delay cost model 116. It will be appreciated that each of the models comprises a simulation that simulates one or more aspects of the operational environment of a fleet of vehicles. As described in more detail below and in one potential advantage of the present disclosure, integrating these various models/simulations into a single probabilistic operational simulation 102 enables more detailed and accurate insights into the operation of the fleet of vehicles, including interactions among the models/simulations and cascading effects.

As described in more detail below, in other examples the operational simulation can include additional operational models that can enhance fidelity of operational impact assessments and corresponding determinations of delay cost metrics. Examples of other operational models include models of planned maintenance requirements, models of maintenance resources, models of sustainment products (e.g., aircraft health management, real-time weather data utilization) and their effects, parts availability models, cancellation/ferry/swap/spare models, etc. Different applications can advantageously implement different collections of models. For example, aircraft route simulations can include the use of taxi/tow models.

The operational data 108 includes data used by the plurality of operational models to perform the operational simulation 102. In the depicted example, the operational data 108 includes route data 118 and cost data 120. The operational data 108 can also include other types of data. For example, parts data can be used in conjunction with a parts model to increase fidelity of the operational simulation 102. The route data 118 includes information describing a route schedule that includes a plurality of routes on which the operational simulation can be performed. The route schedule can be defined using vehicle data 122, which describes a fleet of vehicles, and departure/arrival data 124, which describes departure and arrival times at transit locations associated with the fleet of vehicles described in the vehicle data 122. The cost data 120 includes information describing costs associated with different delays and their corresponding causes. As can readily be appreciated, the operational data 108 can be implemented using other organizational schemes and/or formats, and can include additional types of data.

The route model 110 can be implemented with the route data 118 to simulate operation of the route schedule described in the route data 118. The route schedule includes a plurality of routes, each associated with one or more vehicles of the fleet of vehicles. A route can be defined in various ways. In some implementations, a route includes information describing a departure time from a first transit location, an arrival time at a second transit location, and an identification of a vehicle operating on the route. A route can also include other information. For example, in an operational simulation for a fleet of aircraft, a route can include information describing the flight path from a first airport to a second airport (including departure and arrival times), flight phases, flight altitudes, taxi/tow times, etc.

The preparation model 112 describes and simulates tasks to prepare a vehicle for departure and to be performed within a preparation time period—i.e., the time period between the arrival time of a vehicle at a transit location and the departure time of the vehicle for its subsequent route. For example, in an aircraft route simulation, the preparation time period is the ground time of an aircraft between routes (i.e., the time period between landing and take-off for the subsequent route). Example tasks to be performed within the preparation time period include the arrival of the vehicle, the inspection of the vehicle (e.g., for maintenance issues), and the performance of maintenance (e.g., planned and/or unplanned maintenance), if any, on the vehicle. Other example tasks can include cleaning and refueling the vehicle. As can readily be appreciated, the type of tasks simulated can depend on the application. In an aircraft route simulation, the preparation model can be described as a ground model that includes tasks such as passenger deplaning/boarding, the unloading/loading of bags, aircraft taxiing, etc.

The preparation model 112 can model and simulate tasks using discrete and/or probabilistic methods. For example, the task time of a given task within the preparation model can be simulated to take N minutes. Alternatively, the task time can be simulated using a probability distribution (e.g., a normal distribution). Parameters of the probability distribution (e.g., mean, standard deviation, etc.) can be predetermined based on real-world data. The parameters can be updated to reflect any changes in the real-world data. In some implementations, the task time is dependent on various conditions (e.g., type of vehicle, current transit location, available resources, etc.). For example, the preparation model can simulate the task time of a given task differently for different vehicles (e.g., different vehicle models may have different refueling times). As another example, the arrival time can be simulated to have a different probability distribution for different transit locations (e.g., certain transit locations may have more late arrivals statistically due to weather, traffic congestion, etc.).

The task time can also be based on a conditional dependency. In some implementations, simulation of a task time for a given task can depend on the occurrence/non-occurrence of an event. For example, a vehicle arriving late to a transit location (e.g., due to required unplanned maintenance) can affect the task time of the refueling step (e.g., additional wait time on resources needed for the refueling step). The various dependencies described above can be implemented in both discrete and probabilistic simulations. In a similar manner, the delay model 114 can model and simulate delays using discrete and/or probabilistic methods.

As described in more detail below, and in one potential advantage of the present disclosure, integrating the route model 110, preparation model 112, and delay model 114 into the operational simulation 102 enables the operational simulation to perform multivariate analyses utilizing outputs from the models to compute delay times 115. In this manner, the operational simulation 102 can provide additional insights into aspects of the operating environment that are otherwise unavailable using separate models/simulations.

As noted, one or more delay models can be implemented with the operational data 108 to model and output delays that can occur during routes of the route schedule over a given timeframe. In the example of FIG. 1 a single delay model 114 is utilized. As described in more detail below, and in one potential advantage of the present disclosure, the delay cost model 116 can receive delay times 115 from the delay model 114 and compute and output delay cost metrics 128 over the timeframe.

Information describing the delays can be organized in various ways. In some implementations, the delay model 114 describes occurrence probabilities associated with different delays. The delay model 114 uses operational data 108 and/or data from the preparation model 112 to simulate occurrences (or non-occurrence) of delays in the route schedule and to compute corresponding information including delay times 115. As described in more detail below, these delay times 115 are provided to the delay cost model 116 to compute delay cost metrics based on the delay times.

In some examples the operational models include a variety of probabilistic delay models that simulate potential sources of delays, such as probabilistic unplanned maintenance delay models, probabilistic aircraft preparation delay models, probabilistic air traffic control delay models, and/or probabilistic airport operations delay models. In one example, the delay model 114 is a probabilistic unplanned maintenance delay model that determines unplanned maintenance time based on simulated faults and information provided by a fault model (not shown) and fault data. A fault refers to any indication describing potential issues with a vehicle, such as failure of a part of the vehicle. The unplanned maintenance time can be based on various factors, such as the repair resources associated with the simulated fault and the maintenance capabilities of the current transit location. In some implementations, the repair resources include probabilities of time resources. For example, the repair resources can include a probability distribution for each fault type describing the likelihood of different unplanned maintenance times for the given fault type. The unplanned maintenance delay model can utilize such information to simulate an unplanned maintenance time for repairing a simulated fault (e.g., a probabilistic drawing can be performed using the probability distribution associated with the simulated fault type).

Information from the preparation model 112 provides context that can determine the impact, if any, that the unplanned maintenance time has on the route schedule. For example, the preparation model 112 can provide schedule slack information, which describe the slack time, if any, between routes for a given vehicle. Slack time is a period of time within the preparation time period that provides a buffer in which tasks can be performed without affecting the departure time of the subsequent route. For example, slack time can include scheduled time in the route schedule intended for providing a buffer period for any delayed route to “catch up.” Slack time can also include any extra time provided due to early completion of preparation tasks—e.g., early simulated arrival times. As such, in some cases, the route schedule may be unaffected by any unplanned maintenance that is to be performed. As another example, the arrival time simulated in the preparation model 112 can affect whether the unplanned maintenance time causes a delay for the next route in the route schedule. An arrival time earlier than expected may provide a longer buffer period in which unplanned maintenance can be performed without causing a delay.

In one example, the operational simulation 102 may run a scenario over a one year timeframe that examines cost implications resulting from a vehicle fault that requires unplanned maintenance. Using an unplanned maintenance delay model, the simulation determines that the vehicle operator is stocking an insufficient number of parts needed to repair the fault at certain airports. This situation is causing delays resulting from the need to borrow parts from another operator or have parts delivered from another source. Additionally, in this example the fault can be repaired only at particular transit locations. Accordingly, the simulation also determines that increased delays are experienced at other locations that vehicles are frequently visiting.

Accordingly, using delay times 115 provided by the delay model 114, the delay cost model 116 determines and outputs delay cost metrics 128 based on the scenario described above. In some examples, and in another potential advantage of the present disclosure, the delay cost model 116 utilizes one or more non-linear functions to determine delay cost metrics 128. In some examples, the relationship between delay time and delay cost is non-linear such that as the length of a delay grows the associated costs rise more quickly. In one potential example of an operational environment with a delay cost model 116 that utilizes a non-linear function, a delay of five minutes corresponds to zero delay costs (because, for example, passengers would still have time to arrive at their connecting gate), a delay of 30 minutes corresponds to delay costs of $1/minute, and a delay of 40 minutes corresponds to $10/minute. It will be appreciated that a wide variety of non-linear delay cost functions can be utilized by the delay cost model 116. In other examples, the delay cost model 116 comprises a linear function.

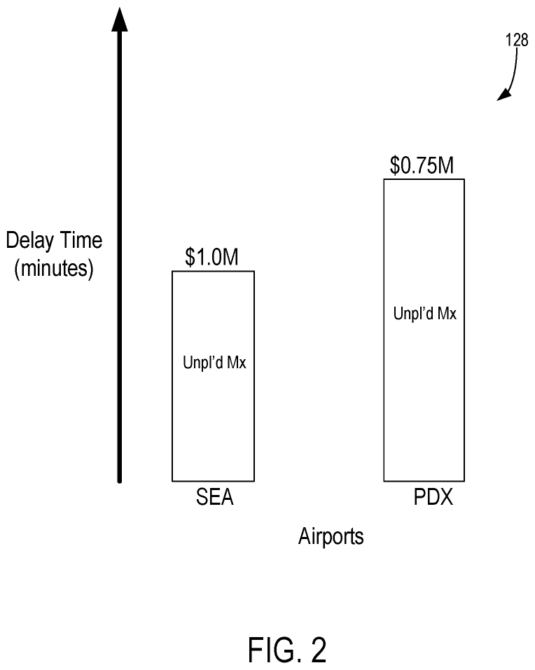

Turning now to FIG. 2, another example of a representation of delay cost metrics 128 output by the delay cost model 116 in the form of stacked bar charts presented on a display is illustrated. In this example and as described below, the delay cost model 116 utilizes a non-linear delay cost function. With reference to the example described above regarding a vehicle fault that requires unplanned maintenance, the total delay times and associated delay costs simulated in this scenario at two airports over a one year timeframe are represented. In this example and as shown in the bar charts, the total delay time at the PDX airport was greater than the total delay time at the SEA airport. However, most of the delays at PDX were shorter delays corresponding to zero or relatively low delay costs, while many of the delays at SEA were longer delays corresponding much higher delay costs. Thus, in this example the associated delay costs at PDX of $0.75M were 25% lower than the delay costs at SEA of $1.0M, despite longer delay times at PDX.

Advantageously, in this example by utilizing a non-linear delay cost function in the delay cost model 116 integrated into the operational simulation 102, delay cost metrics 128 are generated and output that enable operators to gain valuable insights into particular aspects of their operational environments. For example, utilizing the delay cost metrics of FIG. 2, an operator can take particular actions to reduce the delay costs at SEA, such as contracting with a maintenance organization at that airport so that unplanned maintenance events can be addressed and repaired faster.

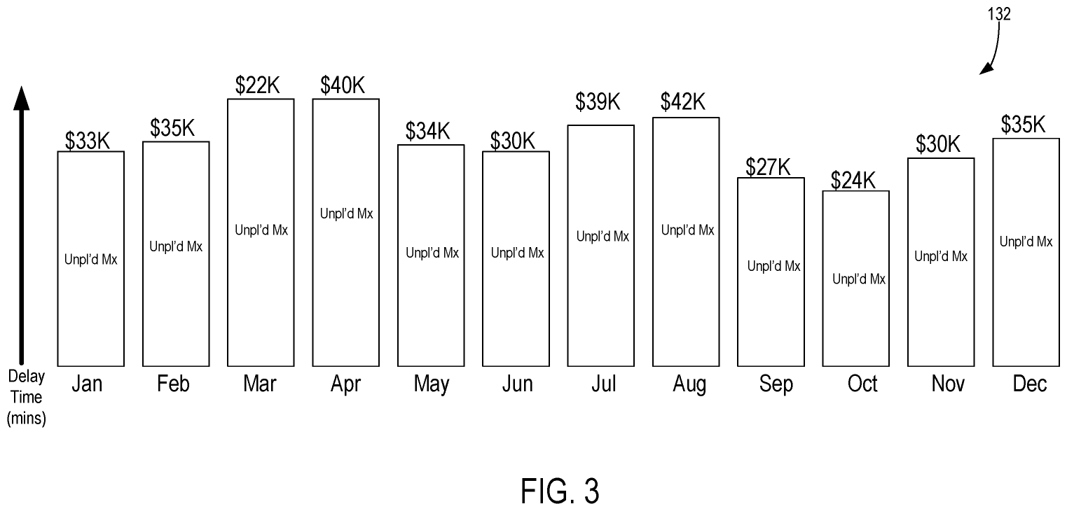

In some examples, the delay cost model 116 can generate a plurality of delay cost metrics 128 that comprises a delay cost distribution over the timeframe of an operational simulation scenario. With reference now to FIG. 3 and the previous example, in one example the timing of the unplanned maintenance delays at the PDX airport are determined and plotted over a one year timeframe. Advantageously in this example, because the unplanned maintenance delay model and delay cost model are integrated into the operational simulation, the simulation can generate a delay cost distribution that reveals patterns of delay costs across the timeframe of the scenario. In this example, the distribution 132 depicted in FIG. 3 shows a clustering of increased delay times in March and April, while also revealing significantly higher delay costs in April as compared with March. Advantageously, with this data an operator can focus attention and corrective efforts on the higher-cost unplanned maintenance delays occurring in April. Additionally and as described further below, in examples where multiple models/simulations are integrated into the operational simulation 102, the fidelity and accuracy of the simulated delay costs are further increased, along with the number of potential options to address and reduce the identified costs.

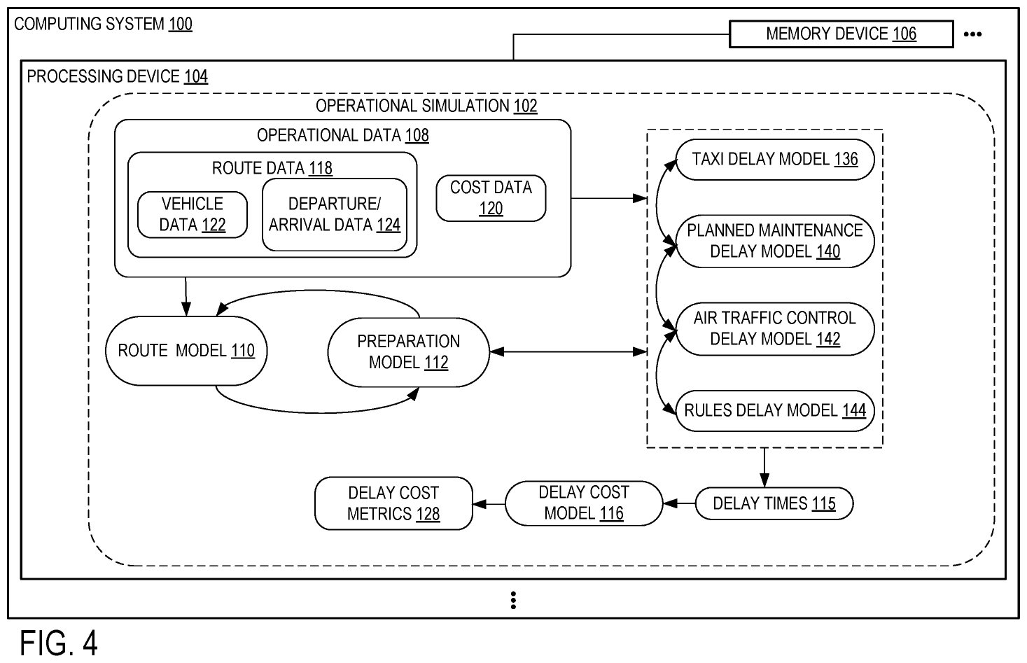

In other examples additional and/or different delay models/simulations can be integrated into the operational simulation 102. The additional and/or different delay models can model and simulate delays using discrete and/or probabilistic methods. With reference now to FIG. 4, in one example a taxi delay model 136, planned maintenance delay model 140, air traffic control delay model 142, and rules delay model 144 are integrated into the operational simulation 102. The taxi delay model 136 simulates aircraft traveling from runway to gate and vice versa and their associated delay times. The planned maintenance delay model 140 simulates planned maintenance operations for the fleet of aircraft and associated delay times. The air traffic control delay model 142 simulates air traffic control operations and their impacts on aircraft arrival/departure times and associated delay times. The rules delay model 144 simulates operational guidelines and restrictions imposed by the FAA and associated delay times. As described further below, in this example the operational simulation 102 utilizes the plurality of integrated delay models to compute delay times occurring over the timeframe of a simulation scenario.

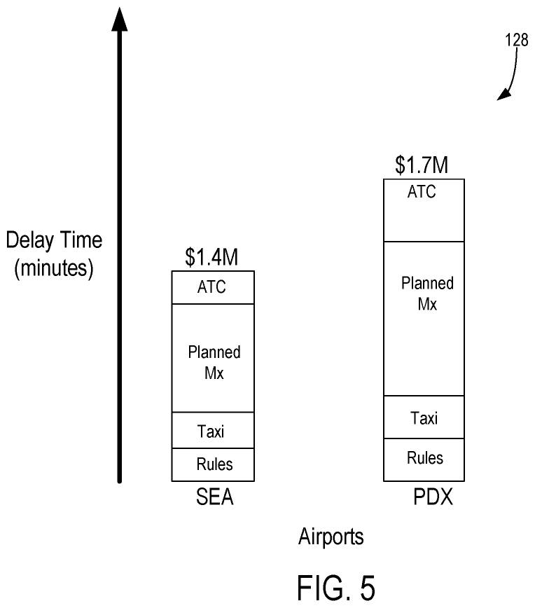

With reference now to FIG. 5, in this example representations of delay cost metrics 128 output by the delay cost model 116 in the form of stacked bar charts presented on a display are illustrated. In this example, delay times simulated by the taxi delay model 136, planned maintenance delay model 140, air traffic control delay model 142, and rules delay model 144 for aircraft at the SEA and PDX airports over a one year timeframe are represented. In this example and as shown in the bar charts, the total delay time and total delay costs at PDX were greater than the total delay time and delay costs at SEA. Additionally, in one potential advantage of this example, these representations reveal the individual contributions of each type of delay to the total delay minutes simulated in this scenario. In this example, these delay cost metrics 128 alert an operator that both air traffic control (ATC) and planned maintenance (Planned Mx) delays are higher at PDX over the timeframe. Given that aircraft operators have limited to zero ability to control/change ATC operations, this information assists an operator in focusing their cost mitigation efforts on aspects within their control, such as the planned maintenance operations.

As noted above, in one potential advantage of the present disclosure, the computing system 100 integrates multiple delay models/simulations into a single operational simulation 102 to generate interactions among a plurality of component simulations, which enables more detailed and accurate insights into the operation of the fleet of vehicles that would be unavailable using separate simulations. In some examples, the operational simulation 102 determines at least one cascading effect arising from interactions among a plurality of models that each generate component simulations, and utilizes the cascading effect to compute one or more delay times occurring over the timeframe of the scenario.

In one example scenario, a component simulation generated by the taxi delay model 136 includes a draw from a corresponding probability distribution of 15 minutes. This 15 minute taxi delay time results in a cascading effect in the component simulation generated by the preparation model 112; namely, because the aircraft's arrival at its scheduled gate is delayed by 15 minutes, a fuel truck assigned to the aircraft has traveled to the other side of the airport to fuel another aircraft. Thus, this 15 minute taxi delay causes a cascading delay of an additional 20 minutes in the component simulation generated by the preparation model 112 to wait for another available fuel truck.

In another potential advantage of the present disclosure, an operator can run a variety of scenarios with changes to one or more of the operational models to simulate different possible configurations and compute corresponding delay cost metrics. In one example, a scenario introduces a change to the rules delay model 144 in which the FAA implements a new rule increasing the minimum separation distance between aircraft from 10,000 feet to 11,000 feet. This rule change can affect the rate at which aircraft can land at their destinations and correspondingly cause delays. The operational simulation 102 can run a first scenario utilizing the current 10,000 feet of separation rule, utilize the delay model(s) to compute a plurality of delay times occurring over the scenario timeframe, and utilize the delay cost model to compute and output corresponding delay cost metrics over the timeframe.

Next, the operational simulation 102 can run a second scenario utilizing the new 11,000 feet of separation rule, utilize the delay model(s) to compute a second plurality of delay times occurring over the timeframe, and utilize the delay cost model to compute and output corresponding delay cost metrics over the timeframe. Advantageously, by simulating this rule change and the corresponding cascading effects in simulations generated by the route model 110 and potentially other models, the delay cost model 116 can use the calculated delay times 115 to determine and output delay cost metrics associated with the change. For example, where the simulated route schedules include sufficient schedule slack time, the corresponding delay costs can be lower. In other examples, the rule change can cause cascading delays in several simulations generated by several corresponding models that result in significant delay costs. Advantageously, the operational simulation 102 can utilize the integrated models to simulate a variety of potential changes to the operational environment and generate corresponding delay cost metrics resulting from those changes.

In some examples, the operational simulation 102 can utilize one or more integrated sustainment models that supplement the operational simulation with sustainment operational data related to operating the plurality of vehicles over the timeframe. Examples of a sustainment model include an aircraft health management model that simulates an aircraft health management system that uses real-time in-flight aircraft data to provide fault forwarding, troubleshooting, and historical fix information to aircraft personnel, thereby reducing schedule interruptions and increasing maintenance and operational efficiencies. Another example of a sustainment model is a weather updates model that simulates a weather update system that uses real-time wind and temperature information to suggest in-flight routing updates that reduce flight delays and improve fuel economy.

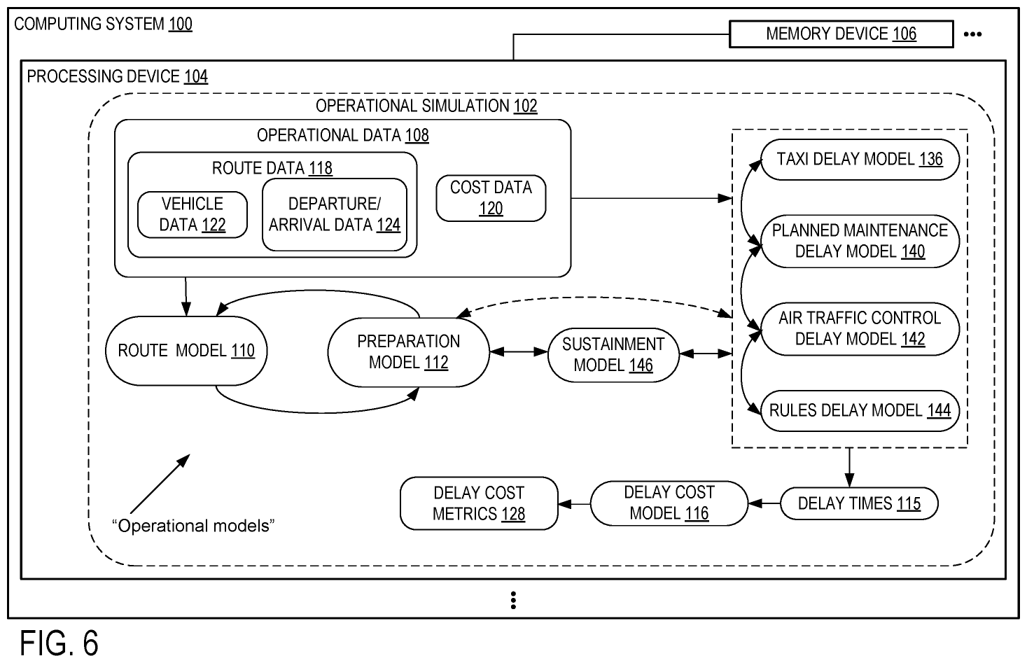

With reference now to FIG. 6, the computing system 100 of FIG. 4 is illustrated with a sustainment model 146 integrated into the operational simulation 102. In one example, the sustainment model 146 is a weather updates (WU) model that simulates a weather update system that uses real-time wind and temperature information to suggest in-flight routing updates. In this manner, while an aircraft is in flight, the weather update system can provide pilots with real-time routing updates that reduce flight delays and improve fuel economy.

The operational simulation 102 can run a first scenario without the weather update model, utilize the delay models to compute a plurality of delay times occurring over the scenario timeframe, and utilize the delay cost model to compute and output corresponding delay cost metrics over the timeframe. Next, the operational simulation 102 can run another scenario utilizing the weather update model, compute a second plurality of delay times occurring over the timeframe with the delay models, and utilize the delay cost model to compute and output corresponding delay cost metrics over the timeframe.

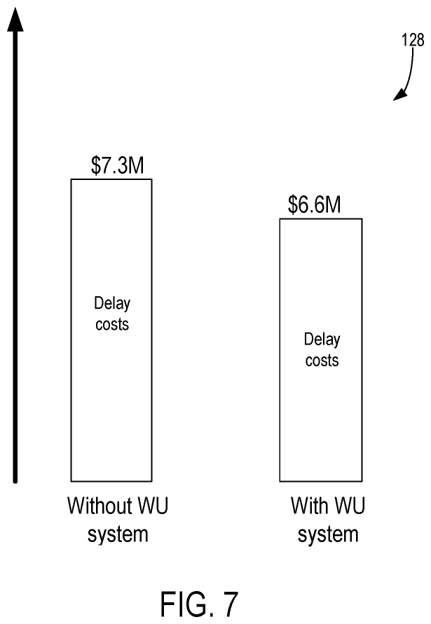

Advantageously, by simulating the implementation of the weather update system, its corresponding reductions in flight delays, and any cascading effects in simulations generated by the route model 110 and potentially other models, the delay cost model 116 can use the calculated delay times 115 to determine and output delay cost metrics associated with the implementation of this sustainment model 146. For example, using route data 118 and vehicle data 122 for a fleet of aircraft, the operational simulation can run multiple scenarios with and without the sustainment model 146 to demonstrate potential delay cost and fuel cost savings provided by this model. FIG. 7 shows one example of delay costs determined by the delay cost model 116 for a first scenario comprising operating a fleet of aircraft over a six month period without utilizing the weather update system, and the delay costs for a second scenario comprising operating the fleet of aircraft over the six month period while utilizing the weather update system.

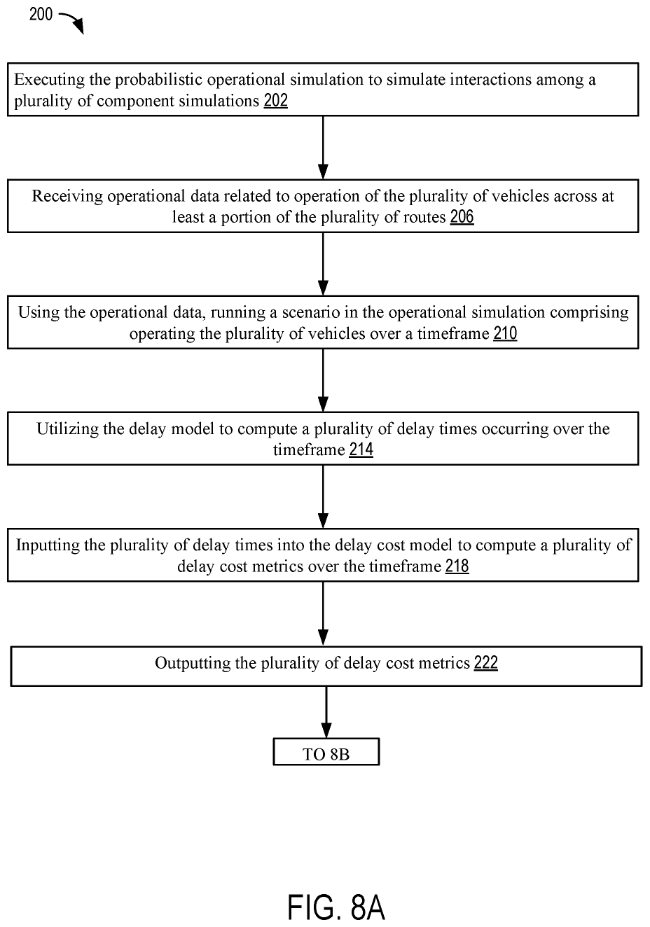

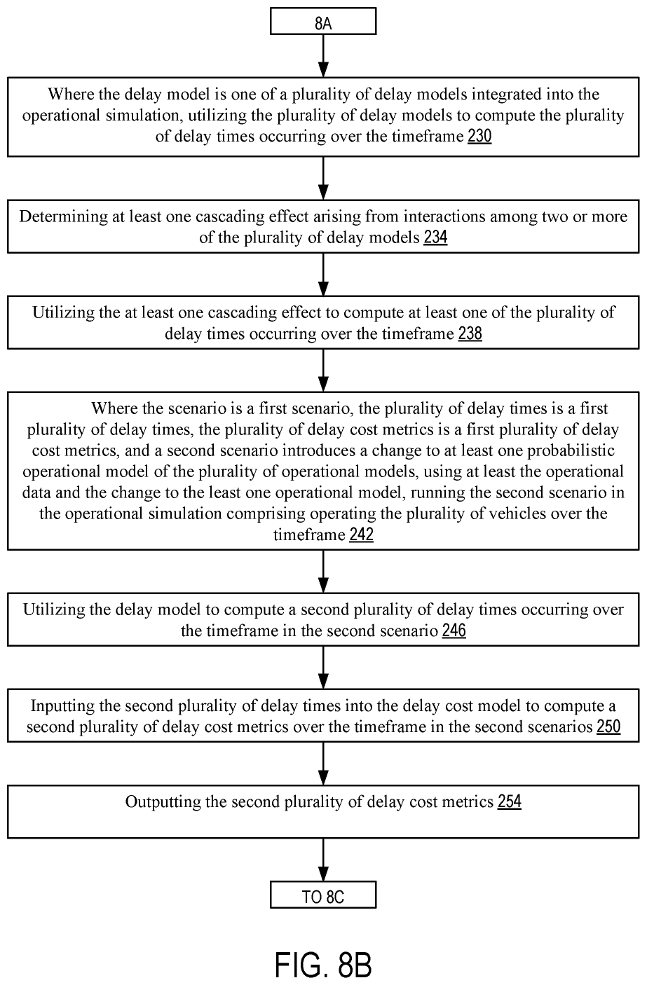

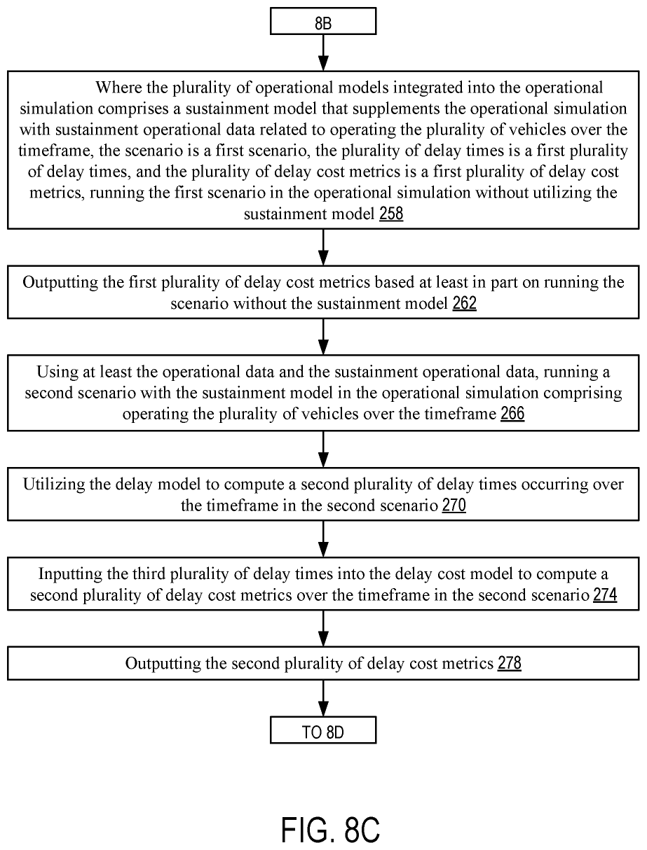

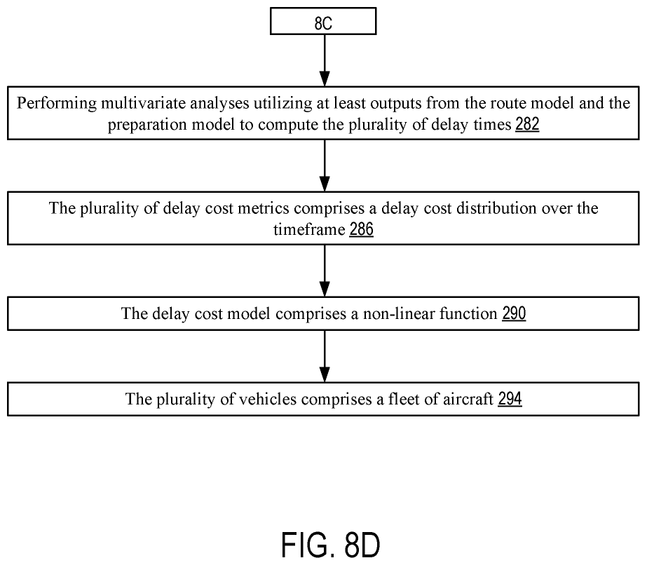

FIGS. 8A-8D show a flow diagram of an example method 200 for determining a plurality of delay cost metrics in a probabilistic operational simulation for a plurality of vehicles. The following description of method 200 is provided with reference to the computing system 100 and related components described herein and shown in FIGS. 1-7. In other examples, the method 200 can be performed with other computing devices and in other contexts using other suitable devices and components. The method 200 includes, at step 202, executing the probabilistic operational simulation to generate interactions among a plurality of component simulations. As noted above, the probabilistic operational simulation comprises a plurality of operational models that generate component simulations and are integrated into the operational simulation, thereby enabling the operational simulation to generate interactions among the component simulations. In some examples the plurality of operational models comprises a route model comprising information describing a route schedule comprising a plurality of routes for the plurality of vehicles, a preparation model comprising information describing tasks to prepare a vehicle for departure, and a delay model for computing delay information. A delay cost model for computing delay cost metrics is also integrated into the operational simulation.

At 206 the method 200 includes receiving operational data related to operation of the plurality of vehicles across at least a portion of the plurality of routes. At 210 the method includes, using the operational data, running a scenario in the operational simulation comprising operating the plurality of vehicles over a timeframe. At 214 the method 200 includes utilizing the delay model to compute a plurality of delay times occurring over the timeframe. At 218 the method 200 includes inputting the plurality of delay times into the delay cost model to compute a plurality of delay cost metrics over the timeframe. At 222 the method 200 includes outputting the plurality of delay cost metrics.

With reference now to FIG. 8B, at 230 the method 200 includes, wherein the delay model is one of a plurality of delay models integrated into the operational simulation, utilizing the plurality of delay models to compute the plurality of delay times occurring over the timeframe. At 234 the method 200 includes determining at least one cascading effect arising from interactions among two or more of the plurality of delay models. At 238 the method 200 includes utilizing the at least one cascading effect to compute at least one of the plurality of delay times occurring over the timeframe. At 242 the method 200 includes, wherein the scenario is a first scenario, the plurality of delay times is a first plurality of delay times, the plurality of delay cost metrics is a first plurality of delay cost metrics, and a second scenario introduces a change to at least one probabilistic operational model of the plurality of operational models, using at least the operational data and the change to the least one operational model, running the second scenario in the operational simulation comprising operating the plurality of vehicles over the timeframe.

At 246 the method 200 includes utilizing the delay model to compute a second plurality of delay times occurring over the timeframe in the second scenario. At 250 the method 200 includes inputting the second plurality of delay times into the delay cost model to compute a second plurality of delay cost metrics over the timeframe in the second scenario. At 254 the method 200 includes outputting the second plurality of delay cost metrics. With reference now to FIG. 8C, at 258 the method 200 includes, wherein the plurality of operational models integrated into the operational simulation comprises a sustainment model that supplements the operational simulation with sustainment operational data related to operating the plurality of vehicles over the timeframe, the scenario is a first scenario, the plurality of delay times is a first plurality of delay times, and the plurality of delay cost metrics is a first plurality of delay cost metrics, running the first scenario in the operational simulation without utilizing the sustainment model.

At 262 the method 200 includes outputting the first plurality of delay cost metrics based at least in part on running the scenario without the sustainment model. At 266 the method 200 includes using at least the operational data and the sustainment operational data, running a second scenario with the sustainment model in the operational simulation comprising operating the plurality of vehicles over the timeframe. At 270 the method 200 includes utilizing the delay model to compute a second plurality of delay times occurring over the timeframe in the second scenario. At 274 the method 200 includes inputting the second plurality of delay times into the delay cost model to compute a second plurality of delay cost metrics over the timeframe in the second scenario. At 278 the method 200 includes outputting the second plurality of delay cost metrics.

With reference now to FIG. 8D, at 282 the method 200 includes performing multivariate analyses utilizing at least outputs from the route model and the preparation model to compute the plurality of delay times. At 286 the method 200 includes wherein the plurality of delay cost metrics comprises a delay cost distribution over the timeframe. At 290 the method 200 includes wherein the delay cost model comprises a non-linear function. At 294 the method 200 includes wherein the plurality of vehicles comprises a fleet of aircraft.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 9 schematically shows a non-limiting embodiment of a computing system 300 that can enact one or more of the methods and processes described above. Computing system 300 is shown in simplified form. Computing system 300 may embody the computing system 100 described above and illustrated in FIGS. 1, 4, and 6. Components of computing system 300 may be included in one or more personal computers, server computers, tablet computers, network computing devices, mobile computing devices, mobile communication devices (e.g., smart phone), and/or other computing devices.

Computing system 300 includes a logic processor 302, volatile memory 304, and a non-volatile storage device 306. Computing system 300 may optionally include a display subsystem 308, input subsystem 310, communication subsystem 312, and/or other components not shown in FIG. 9.

Logic processor 302 includes one or more physical devices configured to execute instructions. For example, the logic processor may be configured to execute instructions that are part of one or more applications, programs, routines, libraries, objects, components, data structures, or other logical constructs. Such instructions may be implemented to perform a task, implement a data type, transform the state of one or more components, achieve a technical effect, or otherwise arrive at a desired result.

The logic processor may include one or more physical processors configured to execute software instructions. Additionally or alternatively, the logic processor may include one or more hardware logic circuits or firmware devices configured to execute hardware-implemented logic or firmware instructions. Processors of the logic processor 302 may be single-core or multi-core, and the instructions executed thereon may be configured for sequential, parallel, and/or distributed processing. Individual components of the logic processor optionally may be distributed among two or more separate devices, which may be remotely located and/or configured for coordinated processing. Aspects of the logic processor may be virtualized and executed by remotely accessible, networked computing devices configured in a cloud-computing configuration. In such a case, these virtualized aspects are run on different physical logic processors of various different machines, it will be understood.

Volatile memory 304 may include physical devices that include random access memory. Volatile memory 304 is typically utilized by logic processor 302 to temporarily store information during processing of software instructions. It will be appreciated that volatile memory 304 typically does not continue to store instructions when power is cut to the volatile memory 304.

Non-volatile storage device 306 includes one or more physical devices configured to hold instructions executable by the logic processors to implement the methods and processes described herein. When such methods and processes are implemented, the state of non-volatile storage device 306 may be transformed—e.g., to hold different data.

Non-volatile storage device 306 may include physical devices that are removable and/or built in. Non-volatile storage device 306 may include optical memory, semiconductor memory, and/or magnetic memory, or other mass storage device technology. Non-volatile storage device 306 may include nonvolatile, dynamic, static, read/write, read-only, sequential-access, location-addressable, file-addressable, and/or content-addressable devices. It will be appreciated that non-volatile storage device 306 is configured to hold instructions even when power is cut to the non-volatile storage device 306.

Aspects of logic processor 302, volatile memory 304, and non-volatile storage device 306 may be integrated together into one or more hardware-logic components. Such hardware-logic components may include field-programmable gate arrays (FPGAs), program-and application-specific integrated circuits (PASIC/ASICs), program- and application-specific standard products (PSSP/ASSPs), system-on-a-chip (SOC), and complex programmable logic devices (CPLDs), for example.

The terms “module,” “program,” and “engine” may be used to describe an aspect of computing system 300 typically implemented in software by a processor to perform a particular function using portions of volatile memory, which function involves transformative processing that specially configures the processor to perform the function. Thus, a module, program, or engine may be instantiated via logic processor 302 executing instructions held by non-volatile storage device 306, using portions of volatile memory 304. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc.

When included, display subsystem 308 may be used to present a visual representation of data held by non-volatile storage device 306. The visual representation may take the form of a graphical user interface (GUI). As the herein described methods and processes change the data held by the non-volatile storage device, and thus transform the state of the non-volatile storage device, the state of display subsystem 308 may likewise be transformed to visually represent changes in the underlying data. For example, computing system 100 can output calculated delay cost metrics in various visual representations that are displayed by display subsystem 308, such as in a GUI. Display subsystem 308 may include one or more display devices utilizing virtually any type of technology. Such display devices may be combined with logic processor 302, volatile memory 304, and/or non-volatile storage device 306 in a shared enclosure, or such display devices may be peripheral display devices.

When included, input subsystem 310 may comprise or interface with one or more user-input devices such as a keyboard, mouse, touch screen, camera, or microphone.

When included, communication subsystem 312 may be configured to communicatively couple various computing devices described herein with each other, and with other devices. Communication subsystem 312 may include wired and/or wireless communication devices compatible with one or more different communication protocols. As non-limiting examples, the communication subsystem may be configured for communication via a wired or wireless local-or wide-area network, broadband cellular network, etc. In some embodiments, the communication subsystem may allow computing system 300 to send and/or receive messages to and/or from other devices via a network such as the Internet.

“And/or” as used herein means any or all of multiple stated possibilities. For example, the phrase “element A and/or element B” covers embodiments having element A alone, element B alone, or elements A and B taken together.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

Further, the disclosure comprises configurations according to the following clauses.

Clause 1. A computing system for computing a plurality of delay cost metrics in a probabilistic an operational simulation for a plurality of vehicles, the computing system comprising: one or more processing devices configured to: execute the probabilistic operational simulation to generate interactions among a plurality of component simulations, wherein: a plurality of operational models is integrated into the probabilistic operational simulation and generates the component simulations, the plurality of operational models comprising: a route model comprising information describing a route schedule comprising a plurality of routes for the plurality of vehicles; a preparation model comprising information describing tasks to prepare a vehicle for departure; and a delay model for computing delay information; and a delay cost model for computing delay cost metrics is integrated into the probabilistic operational simulation; receive operational data related to operation of the plurality of vehicles across at least a portion of the plurality of routes; using the operational data, run a scenario in the probabilistic operational simulation comprising operating the plurality of vehicles over a timeframe; utilize the delay model to compute a plurality of delay times occurring over the timeframe; input the plurality of delay times into the delay cost model to compute a plurality of delay cost metrics over the timeframe; and output the plurality of delay cost metrics.

Clause 2. The computing system of clause 1, wherein the delay model is one of a plurality of delay models integrated into the operational simulation, and the one or more processing devices are configured to utilize the plurality of delay models to compute the plurality of delay times occurring over the timeframe.

Clause 3. The computing system of clause 2, wherein the one or more processing devices are configured to: determine at least one cascading effect arising from interactions among two or more of the plurality of delay models; and utilize the at least one cascading effect to compute at least one of the plurality of delay times occurring over the timeframe.

Clause 4. The computing system of clauses 1 to 3, wherein the scenario is a first scenario, the plurality of delay times is a first plurality of delay times, the plurality of delay cost metrics is a first plurality of delay cost metrics, and a second scenario introduces a change to at least one probabilistic operational model of the plurality of operational models, wherein the one or more processing devices are configured to: using at least the operational data and the change to the least one probabilistic operational model, run the second scenario in the operational simulation comprising operating the plurality of vehicles over the timeframe; utilize the delay model to compute a second plurality of delay times occurring over the timeframe in the second scenario; input the second plurality of delay times into the delay cost model to compute a second plurality of delay cost metrics over the timeframe in the second scenario; and output the second plurality of delay cost metrics.

Clause 5. The computing system of clauses 1 to 4, wherein the plurality of operational models integrated into the operational simulation comprises a sustainment model that supplements the operational simulation with sustainment operational data related to operating the plurality of vehicles over the timeframe, the scenario is a first scenario, the plurality of delay times is a first plurality of delay times, and the plurality of delay cost metrics is a first plurality of delay cost metrics, wherein the one or more processing devices are configured to: run the first scenario in the operational simulation without utilizing the sustainment model; output the first plurality of delay cost metrics based at least in part on running the first scenario without the sustainment model; using at least the operational data and the sustainment operational data, run a second scenario with the sustainment model in the operational simulation comprising operating the plurality of vehicles over the timeframe; utilize the delay model to compute a second plurality of delay times occurring over the timeframe in the second scenario; input the second plurality of delay times into the delay cost model to compute a second plurality of delay cost metrics over the timeframe in the second scenario; and output the second plurality of delay cost metrics.

Clause 6. The computing system of clauses 1 to 5, wherein running the scenario in the operational simulation comprises performing multivariate analyses utilizing at least outputs from the route model and the preparation model to compute the plurality of delay times.

Clause 7. The computing system of clauses 1 to 6, wherein the plurality of delay cost metrics comprises a delay cost distribution over the timeframe.

Clause 8. The computing system of clauses 1 to 7, wherein the delay cost model comprises a non-linear function.

Clause 9. The computing system of clauses 1 to 8, wherein the plurality of vehicles comprises a fleet of aircraft.

Clause 10. A method for determining a plurality of delay cost metrics in a probabilistic operational simulation for a plurality of vehicles, the method comprising: executing the probabilistic operational simulation to generate interactions among a plurality of component simulations, wherein: a plurality of operational models is integrated into the probabilistic operational simulation and generates the component simulations, the plurality of operational models comprising: a route model comprising information describing a route schedule comprising a plurality of routes for the plurality of vehicles; a preparation model comprising information describing tasks to prepare a vehicle for departure; and a delay model for computing delay information; and a delay cost model for computing delay cost metrics is integrated into the operational simulation; receiving operational data related to operation of the plurality of vehicles across at least a portion of the plurality of routes; using the operational data, running a scenario in the probabilistic operational simulation comprising operating the plurality of vehicles over a timeframe; utilizing the delay model to compute a plurality of delay times occurring over the timeframe; inputting the plurality of delay times into the delay cost model to compute a plurality of delay cost metrics over the timeframe; and outputting the plurality of delay cost metrics.

Clause 11. The method of clause 10, wherein the delay model is one of a plurality of delay models integrated into the operational simulation, and the method further comprises utilizing the plurality of delay models to compute the plurality of delay times occurring over the timeframe.

Clause 12. The method of clause 11, further comprising: determining at least one cascading effect arising from interactions among two or more of the plurality of delay models; and utilizing the at least one cascading effect to compute at least one of the plurality of delay times occurring over the timeframe.

Clause 13. The method of clauses 10 to 12, wherein the scenario is a first scenario, the plurality of delay times is a first plurality of delay times, the plurality of delay cost metrics is a first plurality of delay cost metrics, and a second scenario introduces a change to at least one probabilistic operational model of the plurality of operational models, the method further comprising: using at least the operational data and the change to the least one probabilistic operational model, running the second scenario in the operational simulation comprising operating the plurality of vehicles over the timeframe; utilizing the delay model to compute a second plurality of delay times occurring over the timeframe in the second scenario; inputting the second plurality of delay times into the delay cost model to compute a second plurality of delay cost metrics over the timeframe in the second scenario; and outputting the second plurality of delay cost metrics.

Clause 14. The method of clauses 10 to 13, wherein the plurality of operational models integrated into the operational simulation comprises a sustainment model that supplements the operational simulation with sustainment operational data related to operating the plurality of vehicles over the timeframe, the scenario is a first scenario, the plurality of delay times is a first plurality of delay times, and the plurality of delay cost metrics is a first plurality of delay cost metrics, the method further comprising: running the first scenario in the operational simulation without utilizing the sustainment model; outputting the first plurality of delay cost metrics based at least in part on running the scenario without the sustainment model; using at least the operational data and the sustainment operational data, running a second scenario with the sustainment model in the operational simulation comprising operating the plurality of vehicles over the timeframe; utilizing the delay model to compute a second plurality of delay times occurring over the timeframe in the second scenario; inputting the second plurality of delay times into the delay cost model to compute a second plurality of delay cost metrics over the timeframe in the second scenario; and outputting the second plurality of delay cost metrics.

Clause 15. The method of clauses 10 to 14, wherein running the scenario in the operational simulation comprises performing multivariate analyses utilizing at least outputs from the route model and the preparation model to compute the plurality of delay times.

Clause 16. The method of clauses 10 to 15, wherein the plurality of delay cost metrics comprises a delay cost distribution over the timeframe.

Clause 17. The method of clauses 10 to 16, wherein the delay cost model comprises a non-linear function.

Clause 18. The method of clauses 10 to 17, wherein the plurality of vehicles comprises a fleet of aircraft.

Clause 19. A computing system for computing a plurality of delay cost metrics in a probabilistic operational simulation for a fleet of aircraft, the computing system comprising: one or more processing devices configured to: execute the probabilistic operational simulation to generate interactions among a plurality of component simulations, wherein: a plurality of operational models is integrated into the probabilistic operational simulation and generates the component simulations, the plurality of operational models comprising: a route model comprising information describing a route schedule comprising a plurality of routes for the fleet of aircraft; a preparation model comprising information describing tasks to prepare an aircraft for departure; and a plurality of delay models for computing delay information; and a delay cost model for computing delay cost metrics is integrated into the probabilistic operational simulation; receive operational data related to operation of the fleet of aircraft across at least a portion of the plurality of routes; using the operational data, run a scenario in the probabilistic operational simulation comprising operating the fleet of aircraft over a timeframe; utilize the plurality of delay models to compute a plurality of delay times occurring over the timeframe; input the plurality of delay times into the delay cost model to compute a plurality of delay cost metrics over the timeframe, wherein the plurality of delay cost metrics comprises a delay cost distribution over the timeframe; and output the plurality of delay cost metrics.

Clause 20. The computing system of clause 19, wherein the one or more processing devices are configured to: determine at least one cascading effect arising from interactions among two or more of the plurality of delay models; and utilize the at least one cascading effect to compute at least one of the plurality of delay times occurring over the timeframe.

1. A computing system for computing a plurality of delay cost metrics in a probabilistic operational simulation for a plurality of vehicles, the computing system comprising:
one or more processing devices configured to:
execute the probabilistic operational simulation to generate interactions among a plurality of component simulations, wherein:
a plurality of operational models is integrated into the probabilistic operational simulation and generates the component simulations, the plurality of operational models comprising:
a route model comprising information describing a route schedule comprising a plurality of routes for the plurality of vehicles;
a preparation model comprising information describing tasks to prepare a vehicle for departure; and
a delay model for computing delay information; and
a delay cost model for computing delay cost metrics is integrated into the probabilistic operational simulation;
receive operational data related to operation of the plurality of vehicles across at least a portion of the plurality of routes;
using the operational data, run a scenario in the probabilistic operational simulation comprising operating the plurality of vehicles over a timeframe;
utilize the delay model to compute a plurality of delay times occurring over the timeframe;
input the plurality of delay times into the delay cost model to compute a plurality of delay cost metrics over the timeframe; and
output the plurality of delay cost metrics.

2. The computing system of claim 1, wherein the delay model is one of a plurality of delay models integrated into the operational simulation, and the one or more processing devices are configured to utilize the plurality of delay models to compute the plurality of delay times occurring over the timeframe.

3. The computing system of claim 2, wherein the one or more processing devices are configured to:
determine at least one cascading effect arising from interactions among two or more of the plurality of delay models; and
utilize the at least one cascading effect to compute at least one of the plurality of delay times occurring over the timeframe.

4. The computing system of claim 1, wherein the scenario is a first scenario, the plurality of delay times is a first plurality of delay times, the plurality of delay cost metrics is a first plurality of delay cost metrics, and a second scenario introduces a change to at least one probabilistic operational model of the plurality of operational models, wherein the one or more processing devices are configured to:
using at least the operational data and the change to the least one probabilistic operational model, run the second scenario in the operational simulation comprising operating the plurality of vehicles over the timeframe;
utilize the delay model to compute a second plurality of delay times occurring over the timeframe in the second scenario;
input the second plurality of delay times into the delay cost model to compute a second plurality of delay cost metrics over the timeframe in the second scenario; and
output the second plurality of delay cost metrics.

5. The computing system of claim 1, wherein the plurality of operational models integrated into the operational simulation comprises a sustainment model that supplements the operational simulation with sustainment operational data related to operating the plurality of vehicles over the timeframe, the scenario is a first scenario, the plurality of delay times is a first plurality of delay times, and the plurality of delay cost metrics is a first plurality of delay cost metrics, wherein the one or more processing devices are configured to:
run the first scenario in the operational simulation without utilizing the sustainment model;
output the first plurality of delay cost metrics based at least in part on running the first scenario without the sustainment model;
using at least the operational data and the sustainment operational data, run a second scenario with the sustainment model in the operational simulation comprising operating the plurality of vehicles over the timeframe;
utilize the delay model to compute a second plurality of delay times occurring over the timeframe in the second scenario;
input the second plurality of delay times into the delay cost model to compute a second plurality of delay cost metrics over the timeframe in the second scenario; and
output the second plurality of delay cost metrics.

6. The computing system of claim 1, wherein running the scenario in the operational simulation comprises performing multivariate analyses utilizing at least outputs from the route model and the preparation model to compute the plurality of delay times.

7. The computing system of claim 1, wherein the plurality of delay cost metrics comprises a delay cost distribution over the timeframe.

8. The computing system of claim 1, wherein the delay cost model comprises a non-linear function.

9. The computing system of claim 1, wherein the plurality of vehicles comprises a fleet of aircraft.

10. A method for determining a plurality of delay cost metrics in a probabilistic operational simulation for a plurality of vehicles, the method comprising:
executing the probabilistic operational simulation to generate interactions among a plurality of component simulations, wherein:
a plurality of operational models is integrated into the probabilistic operational simulation and generates the component simulations, the plurality of operational models comprising:
a route model comprising information describing a route schedule comprising a plurality of routes for the plurality of vehicles;
a preparation model comprising information describing tasks to prepare a vehicle for departure; and
a delay model for computing delay information; and
a delay cost model for computing delay cost metrics is integrated into the operational simulation;
receiving operational data related to operation of the plurality of vehicles across at least a portion of the plurality of routes;
using the operational data, running a scenario in the probabilistic operational simulation comprising operating the plurality of vehicles over a timeframe;
utilizing the delay model to compute a plurality of delay times occurring over the timeframe;
inputting the plurality of delay times into the delay cost model to compute a plurality of delay cost metrics over the timeframe; and
outputting the plurality of delay cost metrics.

11. The method of claim 10, wherein the delay model is one of a plurality of delay models integrated into the operational simulation, and the method further comprises utilizing the plurality of delay models to compute the plurality of delay times occurring over the timeframe.

12. The method of claim 11, further comprising:
determining at least one cascading effect arising from interactions among two or more of the plurality of delay models; and
utilizing the at least one cascading effect to compute at least one of the plurality of delay times occurring over the timeframe.

13. The method of claim 10, wherein the scenario is a first scenario, the plurality of delay times is a first plurality of delay times, the plurality of delay cost metrics is a first plurality of delay cost metrics, and a second scenario introduces a change to at least one probabilistic operational model of the plurality of operational models, the method further comprising:
using at least the operational data and the change to the least one probabilistic operational model, running the second scenario in the operational simulation comprising operating the plurality of vehicles over the timeframe;
utilizing the delay model to compute a second plurality of delay times occurring over the timeframe in the second scenario;
inputting the second plurality of delay times into the delay cost model to compute a second plurality of delay cost metrics over the timeframe in the second scenario; and
outputting the second plurality of delay cost metrics.

14. The method of claim 10, wherein the plurality of operational models integrated into the operational simulation comprises a sustainment model that supplements the operational simulation with sustainment operational data related to operating the plurality of vehicles over the timeframe, the scenario is a first scenario, the plurality of delay times is a first plurality of delay times, and the plurality of delay cost metrics is a first plurality of delay cost metrics, the method further comprising:
running the first scenario in the operational simulation without utilizing the sustainment model;
outputting the first plurality of delay cost metrics based at least in part on running the scenario without the sustainment model;
using at least the operational data and the sustainment operational data, running a second scenario with the sustainment model in the operational simulation comprising operating the plurality of vehicles over the timeframe;
utilizing the delay model to compute a second plurality of delay times occurring over the timeframe in the second scenario;
inputting the second plurality of delay times into the delay cost model to compute a second plurality of delay cost metrics over the timeframe in the second scenario; and
outputting the second plurality of delay cost metrics.

15. The method of claim 10, wherein running the scenario in the operational simulation comprises performing multivariate analyses utilizing at least outputs from the route model and the preparation model to compute the plurality of delay times.

16. The method of claim 10, wherein the plurality of delay cost metrics comprises a delay cost distribution over the timeframe.

17. The method of claim 10, wherein the delay cost model comprises a non-linear function.

18. The method of claim 10, wherein the plurality of vehicles comprises a fleet of aircraft.

19. A computing system for computing a plurality of delay cost metrics in a probabilistic operational simulation for a fleet of aircraft, the computing system comprising:
one or more processing devices configured to:
execute the probabilistic operational simulation to generate interactions among a plurality of component simulations, wherein:
a plurality of operational models is integrated into the probabilistic operational simulation and generates the component simulations, the plurality of operational models comprising:
a route model comprising information describing a route schedule comprising a plurality of routes for the fleet of aircraft;
a preparation model comprising information describing tasks to prepare an aircraft for departure; and
a plurality of delay models for computing delay information; and
a delay cost model for computing delay cost metrics is integrated into the probabilistic operational simulation;
receive operational data related to operation of the fleet of aircraft across at least a portion of the plurality of routes;
using the operational data, run a scenario in the probabilistic operational simulation comprising operating the fleet of aircraft over a timeframe;
utilize the plurality of delay models to compute a plurality of delay times occurring over the timeframe;
input the plurality of delay times into the delay cost model to compute a plurality of delay cost metrics over the timeframe, wherein the plurality of delay cost metrics comprises a delay cost distribution over the timeframe; and
output the plurality of delay cost metrics.

20. The computing system of claim 19, wherein the one or more processing devices are configured to:
determine at least one cascading effect arising from interactions among two or more of the plurality of delay models; and
utilize the at least one cascading effect to compute at least one of the plurality of delay times occurring over the timeframe.
